(19) United States
(12) Patent Application Publication
(10) Pub. No.: US 2004/0031983 A1
(43) Pub. Date: Feb. 19, 2004

(54) Structure of a memory device and fabrication method thereof

(76) Inventors: Weng-Hsing Huang, Hsinchu (TW); Kent Kuohua Chang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/064,799

(22) Filed: Aug. 19, 2002

(51) Int. Cl. H01L 31/0328

(52) U.S. Cl. 257/310

(57) ABSTRACT

A memory device and a fabrication method thereof, wherein the memory device includes a gate oxide layer disposed on a surface of the substrate and a gate disposed on a portion of the gate oxide layer. A buried drain line is located in the substrate beside both sides of the gate and a spacer is disposed beside the sidewalls of the gate. A deep doped region is located in the substrate below a portion of the buried drain line, wherein the buried drain line and the deep doped region together serve as a word line for the memory device. An insulation layer is disposed above the bit line and a word line is disposed above the gate and the insulation layer, perpendicular to a direction of the bit line.

### BACKGROUND OF INVENTION

1. Field of the Invention

The present invention relates to a structure of a memory device and a fabrication method thereof. More particularly, the present invention relates to a structure of a memory device and a fabrication method thereof, wherein the reliability of the device is improved by double implant.

2. Description of Related Art

Memory device, by nature, is a semiconductor device used to store information and data. The storage of digital information is in unit of bit. The information is stored in a cell in the memory device. The specific location of each memory cell is known as an address. In other words, the memory cells in a memory device are arranged in an array, wherein a specific row and column constitutes a specified memory cell address. The memory cells on each row or each column are connected with a common conductive line.

Referring to FIG. 1, FIG. 1 is a schematic, cross-sectional view of a structure of a memory cell device according to the prior art.

Referring to FIG. 1, the conventional fabrication method for a memory device comprises forming a gate oxide layer 102 on a substrate 100. A buried drain line 104, serving as a bit line of the memory device, is then formed in the substrate 100. A field oxide insulation layer 106 is formed on the buried drain line 104 to isolate the buried drain line 104 and the subsequently formed word line. Further, a word line 108 is formed on the gate oxide layer 102 and the field oxide insulation layer 106, wherein the word line 108 is formed perpendicular to the direction of the buried drain line 104.

Accompanying the increase of circuit integration and the miniaturization of device dimension, the linewidth of the buried drain region is also being scaled down. A narrower linewidth, however, would lead to its resistance to increase. Consequently, the current flow of the memory device is reduced and bit line loading would become too high. If the junction depth of the buried drain region is increased to resolve the problem of raised resistance at the linewidith, not only is the short channel effect generated, the problem of junction leakage also occurs. If a high concentration of dopants is used to form a shallow junction of the bit line to obviate the short channel effect and the junction leakage problem due to a deep junction, the overloading problem of the bit line remains unresolved because of the limitation of the solid-phase solubility. Further, in a conventional memory device, a bit line contact is required for every 32 bit lines or 64 bit lines to control the memory device. The formation of a bit line contact, however, is limited by the integration of the device. Lower the number of the bit line contact in order to increase the integration of the device is thus very important.

### SUMMARY OF INVENTION

Accordingly, the present invention provides a structure of a memory device and a fabrication method thereof, wherein the bit line resistance is reduced.

The present invention also provides a structure of a memory device and a fabrication method thereof, wherein the junction of the buried drain line can be shallow without the generation of the short channel effect and the junction leakage problem.

The present invention further provides a structure of a memory device and a fabrication method thereof, wherein the number of the bit line contact in the device is reduced to increase the integration of the device.

In accordance to the present invention, a structure of a memory device is provided, the structure comprises a substrate, a gate oxide layer, a gate, a buried drain line, a spacer, a deep doped region, an insulation layer and a word line. The gate oxide layer is disposed on the substrate surface. The gate is disposed on a part of the gate oxide layer. The buried drain line is positioned in the substrate beside the sides of the gate, while the spacer is disposed on the sidewalls of the gate. Further, the deep doped region is located in the substrate below a portion of the buried drain line, wherein the deep doped region and the buried drain line serve together as a bit line of the memory device. The insulation layer is disposed on the substrate above the bit line. The word line is provided above the gate and the insulation layer to connect the gates on a same row, wherein the word line is perpendicular to a direction of the bit line.

The present invention provides a fabrication method for a memory device, wherein a gate oxide layer is formed on a substrate. A bar-shaped conductive structure is then formed on the gate oxide layer, wherein a cap layer is further formed on the top of the bar-shaped conductive structure. Thereafter, an ion implantation process is performed using the cap layer and the bar-shaped conductive structure as an implantation mask to form a buried drain line in the substrate beside both sides of the bar-shaped conductive structure. Thereafter, a spacer is formed on the sidewall of the bar-shaped conductive structure and the cap layer. Further using the spacer and the cap layer as an ion implantation mask, an ion implantation process is performed to form a deep doped region in the substrate beside both sides of the spacer, wherein the deep doped region is formed in the substrate below a portion of the buried drain line. In the present invention, the buried drain line and the deep doped region together serve as a bit line for the memory device. An insulation layer is then globally formed on the substrate, covering the cap layer, wherein there is an etching selectivity between the insulation layer and the cap layer. Further, there is an etching selectivity between the insulation layer and the spacer. A back etching or a chemical mechanical polishing is performed to remove a portion of the insulation layer until the cap layer is exposed so that the insulation layer only covers the top of the bit line. Thereafter, the cap layer is removed to expose the bar-shaped conductive structure. A conductive layer is formed globally on the substrate, covering the bar-shaped conductive structure. A patterned conductive layer and the bar-shaped conductive structure form a word line and a plurality of gates, wherein the word line connects the gates on a same row.

According to the structure of a memory device and the fabrication method thereof, the bit line is formed with a buried drain line and a deep doped region, the resistance of the bit line of the memory device is thus greatly reduced.

According to the structure of a memory device and the fabrication method thereof, the buried drain line of the device can be shallow to prevent the short channel effect and the junction leakage problem in order to increase the reliability of the device.

According to the structure of a memory device and a fabrication method thereof, the voltage drop across the bit line can be lower to reduce the number of the bit line contacts in the device. The integration of the device can thus increase.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of a memory device according to the prior art; and

FIGS. 2A to 2G are schematic cross-sectional views illustrating the process flow for manufacturing of a memory device according to one aspect of the present invention.

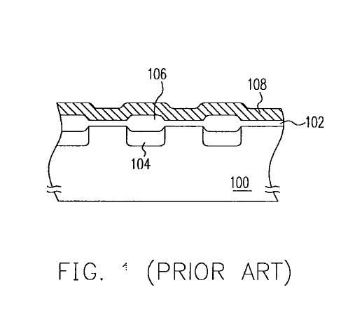

### DETAILED DESCRIPTION

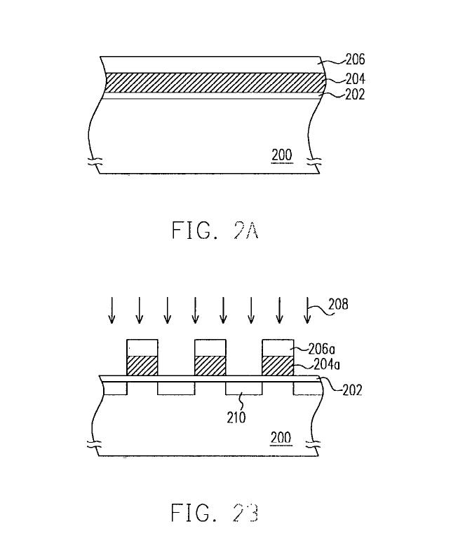

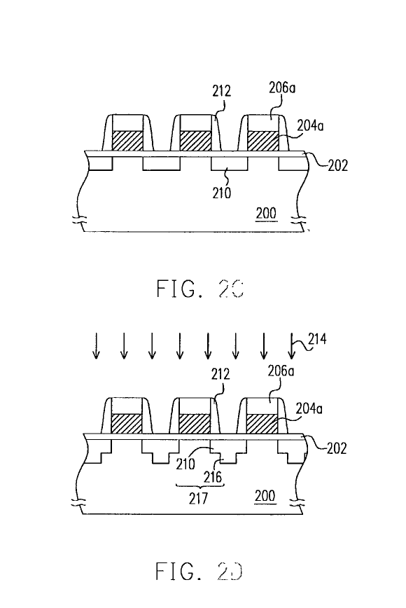

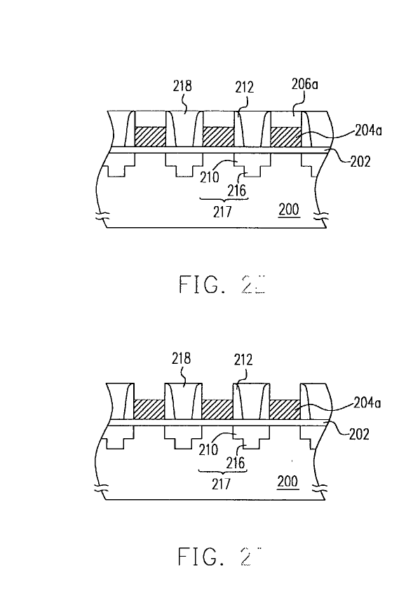

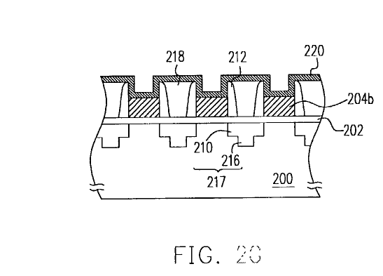

FIGS. 2A to 2G are schematic cross-sectional views illustrating the process flow for manufacturing of a memory device according to one aspect of the present invention.

Referring to FIG. 2A, a gate oxide layer 202 is formed on a substrate 200, wherein the gate oxide layer 202 is formed by a thermal oxidation method. A conductive layer 204 is then formed on the gate oxide layer 202, followed by forming a material layer 206 on the conductive layer 204. According to this aspect of the present invention, a material for the conductive layer 204 includes polysilicon while a material for the material layer 206 includes silicon nitride.

Referring to FIG. 2B, the material layer 206 and the conductive layer 204 are patterned to form a bar-shaped conductive structure 204a and a cap layer 206a on the top of the bar-shaped conductive structure 204a. Using the cap layer 206a and the bar-shaped conductive structure 204a as an implantation mask, an ion implantation 208 is performed to form a buried drain line 210 in the substrate 200 beside both sides of the bar-shaped conductive structure 204a.

In the present invention, the buried drain line 210 is formed after the formation of the gate oxide layer 202 and the bar-shaped conductive structure 204a. The diffusion effect in the buried drain line 210 due to the high temperature when forming the gate oxide layer 202 and the bar-shaped conductive structure 204a is mitigated.

Continuing to FIG. 2C, a spacer 212 is formed on the sidewall of the bar-shaped-conductive structure 204a and the cap layer 206a, wherein there is an etching selectivity between the spacer 212 and the cap layer 206a. According to this aspect of the present invention, the spacer 212 is, for example, silicon oxide. Moreover, forming the spacer 212 includes first forming a conformal oxide layer (not shown) on the substrate 200, followed by back-etching the conformal silicon oxide layer to form the spacer 212.

As shown in FIG. 2D, an ion implantation 214 is conducted to form a deep doped region 216 in the substrate beside the sides of the spacer 212, using the spacer 212 and the cap layer 206a as an implantation mask. The doped region 216 is formed in the substrate 200 under a portion of the buried drain line 210. The doped region 216 and the buried drain line 210 together form a bit line 217 for the memory cell device.

Since the bit line 217 of the memory device of the present invention is formed with the buried bit line 210 and the deep doped region 216 formed below a portion of the buried bit line 210, the resistance of the bit line of the memory device of the present invention can be lower to prevent an increase of the resistance when the device dimension is being scaled down. Further, since the present invention can effectively lower the resistance of the bit line 217, the junction of the buried drain line 210 can be shallower to prevent the short channel effect and the junction leakage problem. The reliability of the device is thereby improved.

Continuing to FIG. 2E, an insulation layer 218 is formed on the bit line 217, wherein there is an etching selectivity between the insulation layer 218 and the cap layer 206a. According to this aspect of the present invention, the insulation layer 218 is, for example, silicon oxide. The insulation layer 218 is formed by, for example, depositing globally an insulation material (now shown) on the substrate 200 using chemical vapor deposition, covering the cap layer 206a. Thereafter, back etching or chemical mechanical polishing is used to remove a portion of the insulation material until the cap layer 206a is exposed.

Thereafter, as shown in FIG. 2F, the cap layer 206a is removed, exposing the bar-shaped conductive structure 204a. Since there is an etching selectivity between the cap layer 206a and the spacer 212, and there is an etching selectivity between cap layer 206a and the insulation layer 218, the insulation layer 218 and the spacer 212 will not be removed during the removal of the cap layer 206a and both layers 212 and 218 are retained.

Continuing to FIG. 2G, a conductive layer (not shown) is formed on the substrate 200, covering the bar-shaped conductive structure 204a and the insulation layer 218, wherein the conductive layer comprises, for example, polysilicon. The conductive layer and the bar-shaped conductive structure 204a are patterned in a direction perpendicular to that of the bit line 217 to form a word line 220 and a plurality of gates 204b. The gates 204b in a same row are connected together by the word line 220.

The memory device of the present invention comprises a substrate 200, a gate oxide layer 202, a gate 204b, a buried drain region 210, a spacer 212, a deep doped region 216, an insulation layer 218 and a word line 220.

The gate oxide layer 202 is disposed on the surface of the substrate 200. The gate 204b is disposed on a portion of the gate oxide layer 202. The buried drain region 210 is positioned in the substrate 200 beside both sides of the gate 204b. The spacer 212 is disposed on the sidewall of the gate 204b. Further a deep doped region is located in the substrate 200 below a portion of the buried drain line 210. In other words, the deep doped region 216 is located in the substrate 200 beside both sides of the spacer 212 and under a portion of the buried drain line 210. The buried drain line 210 and the deep doped region 216 together form a bit line 217 of the memory cell device. The insulation layer 218 is disposed on the substrate 200 above the bit line 217, implying that the insulation layer 218 is positioned only on the substrate 200 that is above the bit line 217, not covering the gate 204b. The word line 220 is disposed above the gate 204b and the insulation layer 218 in a direction perpendicular to the direction of the bit line 217, wherein the gates 204b in a same row are connected together by the word line 220.

Since the bit line 217 of the present invention is formed with the buried drain line 210 and the deep doped region 216, the resistance of the bit line 217 is thus lower to attenuate the problem of an increased resistance due to scaling down of the device dimension. Moreover, the junction of the buried drain line 210 of the present invention can be shallower to prevent the short channel effect and the junction leakage problem to enhance the reliability of the device. Further, the resistance of the bit line 217 of the memory device of the present invention can be effectively decreased to lower the voltage drop across the bit line. The number of the bit line contacts in the device can be reduced to raise the integration of the device.

Accordingly, the structure and the fabrication method for a memory device of the present invention can lower the resistance of the bit line of the memory device. Moreover, the buried bit line of the structure of the memory device and the fabrication method thereof of the present invention can be shallower to prevent the short channel effect and the junction leakage problem in order to enhance the reliability of the device. Further, according to the structure and the fabrication method for a memory device of the present invention, the number of the bit line contacts in the device is reduced to raise the integration of the device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A memory device, comprising
a substrate;
a gate oxide layer, disposed on a surface of the substrate;
a gate, disposed on a portion of the gate oxide layer;
a buried drain line, located in the substrate beside both sides of the gate;
a spacer, disposed on sidewalls of the gate;
a deep doped region, located in the substrate below a part of the buried drain line, wherein the buried drain line and the deep doped region together form a bit line of the memory device;
an insulation layer, disposed above the bit line; and
a word line, disposed above the gate and the insulation layer, perpendicular to a direction of the bit line.

2. The memory device of claim 1, wherein the insulation layer is formed with silicon oxide.

3. The memory device of claim 1, wherein the spacer is formed with silicon oxide.

4. The memory device of claim 1, wherein the word line is formed with a material comprising polysilicon.

5. The memory device of claim 1, wherein the deep doped region is located in the substrate beside both sides of the spacer.

6. A fabrication method for a memory device, comprising:
forming a gate oxide layer on a substrate;
forming a bar-shaped conductive structure on the gate oxide layer, wherein a cap layer is formed on a top of the bar-shaped conductive structure;
forming a buried drain line in the substrate beside both sides of the bar-shaped conductive structure;
forming a spacer on sidewalls of the bar-shaped conductive structure and the cap layer;
forming a deep doped region in the substrate beside both sides of the spacer, wherein the buried drain line and the deep doped region together form a bit line of the memory device;
forming an insulation layer above the bit line;
removing the cap layer;
forming a conductive layer on the substrate; and
patterning the conductive layer and the bar-shaped conductive structure in a direction perpendicular to a direction of the bit line to form a word line and a plurality of gates.

7. The method of claim 6, wherein there is an etching selectivity between the cap layer and the spacer.

8. The method of claim 6, wherein there is an etching selectivity between the cap layer and the insulation layer.

9. The method of claim 6, wherein the cap layer is formed with a material comprising silicon nitride.

10. The method of claim 6, wherein the spacer is formed with a material comprising silicon oxide.

11. The method of claim 6, wherein an insulation layer is formed with a material comprising silicon oxide.

12. The method of claim 6, wherein forming the buried drain line includes performing an ion implantation process using the cap layer and the bar-shaped conductive structure as an implantation mask.

13. The method of claim 6, wherein the deep doped region is formed by performing an ion implantation process using the cap layer and the spacer as an implantation mask.

14. The method of claim 6, wherein forming the insulation layer above the bit line comprises:
forming globally an insulation material on the substrate, the insulation layer covers the cap layer; and
removing a portion of the insulation material until the cap layer is exposed.

15. The method of claim 14, wherein removing the portion of the insulation material includes performing back etching or chemical mechanical polishing.

16. The method of claim 6, wherein forming the bar-shaped conductive structure and the cap layer comprises:
forming sequentially a conductive layer and a material layer on the gate oxide layer; and
patterning the material layer and the conductive layer to form the bar-shaped conductive structure and the cap layer.

17. The method of claim 6, wherein forming the spacer comprises:
forming a conformal silicon layer on the substrate; and
back-etching the conformal silicon oxide layer to form the spacer.
